(19) United States
(12) Patent Application Publication
(10) Pub. No.: US 2012/0250445 A1
(43) Pub. Date: Oct. 4, 2012

(54) SEMICONDUCTOR APPARATUS

(75) Inventors: Yasuharu HOSHINO, Kanagawa (JP); Toshihiko FUNAKI, Kanagawa (JP); Atsunori HIROBE, Kanagawa (JP); Tetsuo FUKUSHI, Kanagawa (JP)

(73) Assignee: Renesas Electronics Corporation, Kanagawa (JP)

(21) Appl. No.: 13/432,967

(22) Filed: Mar. 28, 2012

(30) Foreign Application Priority Data
Mar. 29, 2011 (JP) 2011-073013

(51) Int. Cl. G11C 8/18; G11C 8/00

(52) U.S. Cl. 365/233.1; 365/230.01

(57) ABSTRACT

A semiconductor apparatus includes a programmable logic chip configured to output a control signal, and a memory chip coupled to the programmable logic chip. The memory chip includes a plurality of memory cores, a plurality of bus-interface circuits each configured to couple with the memory cores, and a selection circuit configured to couple the memory cores with one of the bus-interface circuits in response to a predetermined logic level of the control signal.

### CROSS-REFERENCE TO RELATED APPLICATIONS

This application is based upon and claims the benefit of priority from Japanese patent application No. 2011-073013, filed on Mar. 29, 2011, the disclosure of which is incorporated herein in its entirety by reference.

### BACKGROUND

The present invention relates to a semiconductor apparatus, in particular a semiconductor apparatus suitable for preventing the deterioration of data processing performance.

Due to the miniaturization of semiconductor processes, the circuit scale that can be mounted on one semiconductor chip has increased. As a result, in logic LSIs, a number of functions necessary for the system can be mounted on one semiconductor chip. Therefore, in logic LSIs, a larger number of data processes are carried out. Because of this trend, it has been required to improve data transfer performance between a logic LSI and a memory and thereby to improve the overall performance of the system.

Japanese Unexamined Patent Application Publication No. 2009-230792 discloses a solution for this requirement. A multi-port memory (semiconductor apparatus) disclosed in Japanese Unexamined Patent Application Publication No. 2009-230792 includes a memory array that includes a plurality of memory cells disposed at intersections of a plurality of bit lines and a plurality of word lines and is divided into n memory banks (n is integer equal to or greater than 2), m input/output ports (m is integer equal to or greater than 2) that independently inputs/outputs a command, an address, and data from/to each of the memory banks, and a path switch circuit that arbitrarily sets a command signal path, an address signal path, and a data signal path between the memory banks and the input/output ports. The path switch circuit includes crossbar switches that set the connection state of each of the command signal line, the address signal line, and the data signal line between the memory banks and the input/output ports, and a broadcast switch unit that, in a broadcast mode, forms a path through which data read from one memory bank is output to a plurality of ports or data input from one port is written into a plurality of memory banks.

This multi-port memory further includes an arbitration circuit that, when access requests from two or more input/output ports to the same memory bank occur simultaneously in the normal operating mode, accepts an access request from an input/output having a higher priority and prohibits the access request(s) from the remaining input/output port(s). In the broadcast mode, this arbitration circuit also prohibits, for example, accesses from input/output ports other than the input/output port from which the broadcast read command is input.

### SUMMARY

The present inventors have found the following problem. In the multi-port memory (semiconductor apparatus) disclosed in Japanese Unexamined Patent Application Publication No. 2009-230792, it is presumed that when access requests from two or more input/output ports to the same memory bank occur at the same time, the accesses are accepted one by one in the descending order of the priorities of the input/output ports. Therefore, an access from an input/output port having a low priority to the memory bank is delayed. As a result, there has been a problem that the data processing performance deteriorates.

As described above, there is a problem that the data processing performance deteriorates in related-art semiconductor apparatuses.

A first aspect of the present invention is a semiconductor apparatus including a programmable logic chip configured to output a control signal, and a memory chip coupled to the programmable logic chip. The memory chip includes a plurality of memory cores, a plurality of bus-interface circuits each configured to couple with the memory cores, and a selection circuit configured to couple the memory cores with one of the bus-interface circuits in response to a predetermined logic level of the control signal.

Another aspect of the present invention is a semiconductor apparatus including:

a plurality of memory cores;

a plurality of bus-interface circuits that interfaces an access from an external device to the plurality of memory cores; and

a selection circuit that selects a signal path between the bus-interface circuits and the memory cores in such a manner that the bus-interface circuits are connected to mutually different memory cores.

Another aspect of the present invention is a semiconductor apparatus including: a plurality of bus-interface circuits that connect an external bus signal with an internal bus signal; a plurality of memory cores, each of which separately includes a bus-interface connectable to the internal bus signal; and a selection circuit that selects a connection state of the internal bus signal between the plurality of bus-interface circuits and the plurality of memory cores, in which the selection circuit connects each of the memory cores with one of the bus-interface circuits based on externally-supplied setting information, and when the bus-interface circuit is not connected to the memory core by the selection circuit, the but-interface circuit fixes at least one of the external bus signal to a predetermined logic level.

With the above-described circuit configuration, it is possible to prevent the deterioration of the data processing performance.

The present invention can provide a semiconductor apparatus capable of preventing the deterioration of the data processing performance.

### BRIEF DESCRIPTION OF THE DRAWINGS

The above and other aspects, advantages and features will be more apparent from the following description of certain embodiments taken in conjunction with the accompanying drawings, in which:

FIG. 1 is a block diagram showing a semiconductor integrated circuit according to a first embodiment of the present invention;

FIG. 2 is a block diagram showing a semiconductor integrated circuit according to a first embodiment of the present invention;

FIG. 3A is a circuit diagram showing a part of a memory according to a first embodiment of the present invention;

FIG. 3B is a circuit diagram showing a part of a memory according to a first embodiment of the present invention;

FIG. 4A is a table for explaining signal paths within a memory according to a first embodiment of the present invention;

FIG. 4B is a table for explaining signal paths within a memory according to a first embodiment of the present invention;

FIG. 5 is a timing chart showing an operation of a semiconductor integrated circuit according to a first embodiment of the present invention;

FIG. 6A is a cross section showing a semiconductor integrated circuit according to a second embodiment of the present invention;

FIG. 6B is a block diagram showing a semiconductor integrated circuit according to a second embodiment of the present invention;

FIG. 7A is a diagram showing an example in which a semiconductor integrated circuit according to a second embodiment of the present invention is mounted on a board;

FIG. 7B is a diagram showing another example in which a semiconductor integrated circuit according to a second embodiment of the present invention is mounted on a board;

FIG. 8A is a circuit diagram showing a part of a memory according to a third embodiment of the present invention;

FIG. 8B is a table for explaining a mode selection signal within a memory according to a third embodiment of the present invention;

FIG. 9 is a block diagram showing a semiconductor integrated circuit according to an idea prior to the present invention;

FIG. 10A is a timing chart showing an operation of a semiconductor integrated circuit according to an idea prior to the present invention;

FIG. 10B is a timing chart showing an operation of a semiconductor integrated circuit according to an idea prior to the present invention;

FIG. 11A is a block diagram showing a semiconductor integrated circuit according to an idea prior to the present invention; and

FIG. 11B is a block diagram showing a semiconductor integrated circuit according to an idea prior to the present invention.

### DETAILED DESCRIPTION

The first, second, and third embodiments can be combined as desirable by one of ordinary skill in the art.

Firstly, before explaining embodiments according to the present invention, a configuration that has been examined by the inventors of the present application prior to achieving the present invention is explained hereinafter.

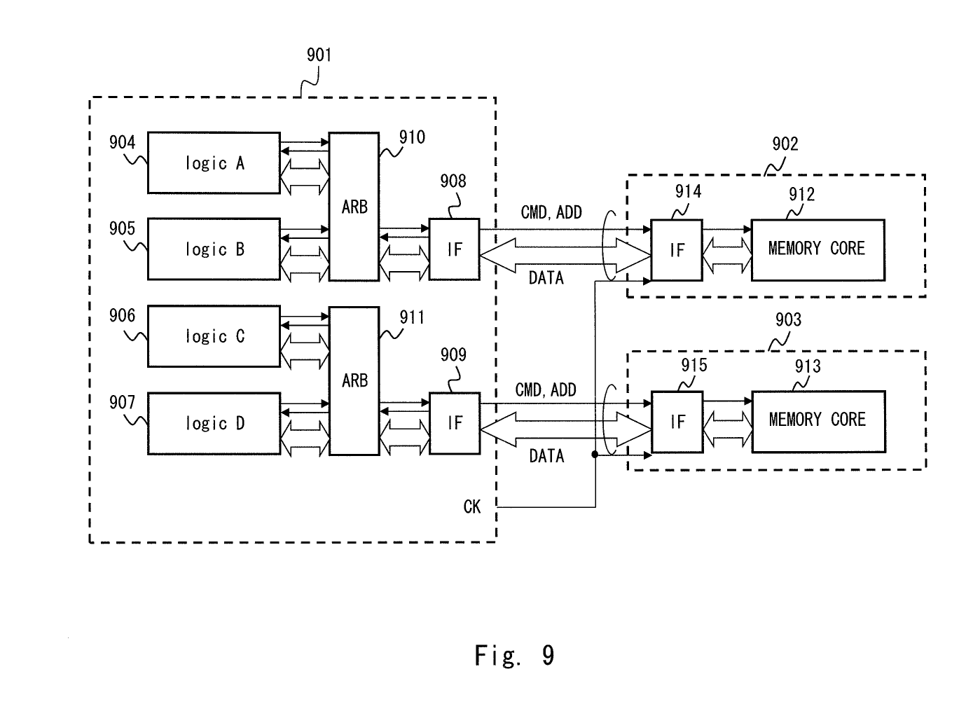

FIG. 9 is a block diagram showing a semiconductor integrated circuit according to an idea prior to achieving the present invention. A semiconductor integrated circuit shown in FIG. 9 includes an integrated circuit 901 including a plurality of functional blocks, and memories (semiconductor apparatuses) 902 and 903. Each of the memories 902 and 903 adopts a shared-memory scheme in which accesses from a plurality of functional blocks are made possible by using only a set of signals (channel) consisting of a data signal, a command signal used to control the reading/writing of data, and an address signal specifying a storage area from/to which data is read/written.

Note that the integrated circuit 901 is, for example, an FPGA (Field Programmable Gate Array) whose configuration can be changed by software. In the field of embedded devices such as digital appliances and network devices, it is possible to provide a plurality of derived products by using common FPGA substrates (platforms). In the following explanation, an example in which the integrated circuit 901 is an FPGA (hereinafter called “PFGA 901”) is explained.

By programming the FPGA 901, the FPGA 901 includes four independent functional blocks 904 to 907, interface circuits 908 and 909, and arbitration circuits 910 and 911.

The functional blocks 904 and 905 share the memory 902 for the temporary saving of working data and the like, and the functional blocks 906 and 907 share the memory 903 for the temporary saving of working data and the like.

The arbitration circuit 910 has a function of determining the order of accesses when the functional blocks 904 and 905 attempt to access the memory 902 at the same time. Similarly, the arbitration circuit 911 has a function of determining the order of accesses when the functional blocks 905 and 906 attempt to access the memory 903 at the same time. The interface circuit 908 is a circuit that interfaces an access from the functional block 904 or 905 to the memory 902. The interface circuit 909 is a circuit that interfaces an access from the functional block 906 or 907 to the memory 903.

The memory 902 includes a memory core 912 and an interface circuit 914. The memory 903 includes a memory core 913 and an interface circuit 915. Each of the memory cores 912 and 913 includes a plurality of memory cells (storage area) for storing data. In each of the memory cores 912 and 913, data is written into a memory cell specified by an address signal, or data stored in a memory cell specified by an address signal is read out. The interface circuit 914 is a circuit that interfaces an access from the FPGA 901 to the memory core 912. The interface circuit 915 is a circuit that interfaces an access from the FPGA 901 to the memory core 913.

That is, the signal transmission between the functional blocks 904 and 905 and the memory core 912 is performed through the interface circuit 908 on the FPGA 901 side and the interface circuit 914 on the memory 902 side. The signal transmission between the functional blocks 906 and 907 and the memory core 913 is performed through the interface circuit 909 on the FPGA 901 side and the interface circuit 915 on the memory 902 side.

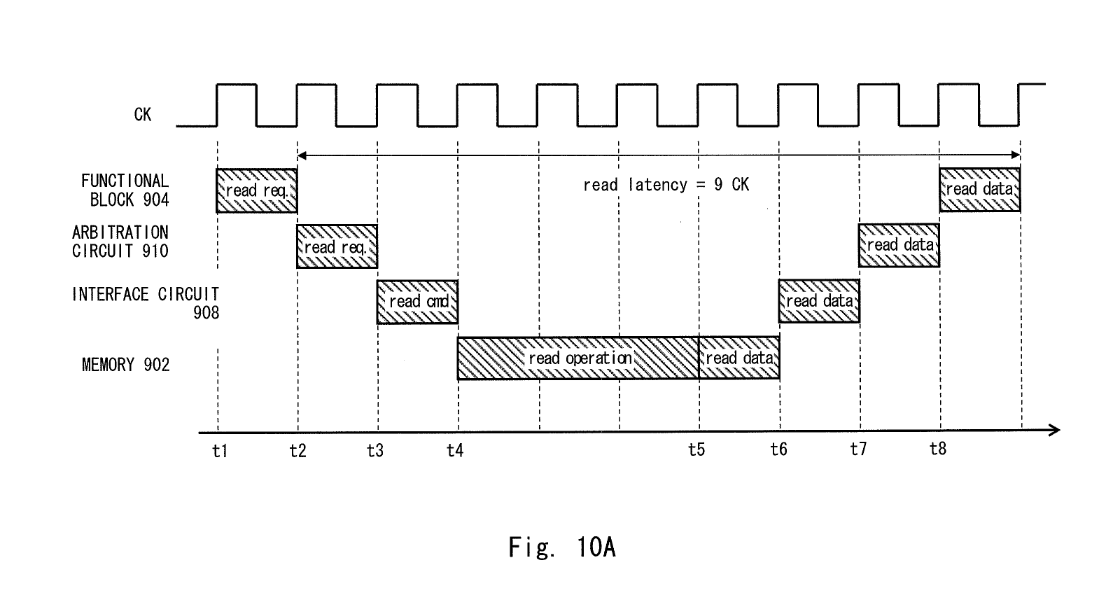

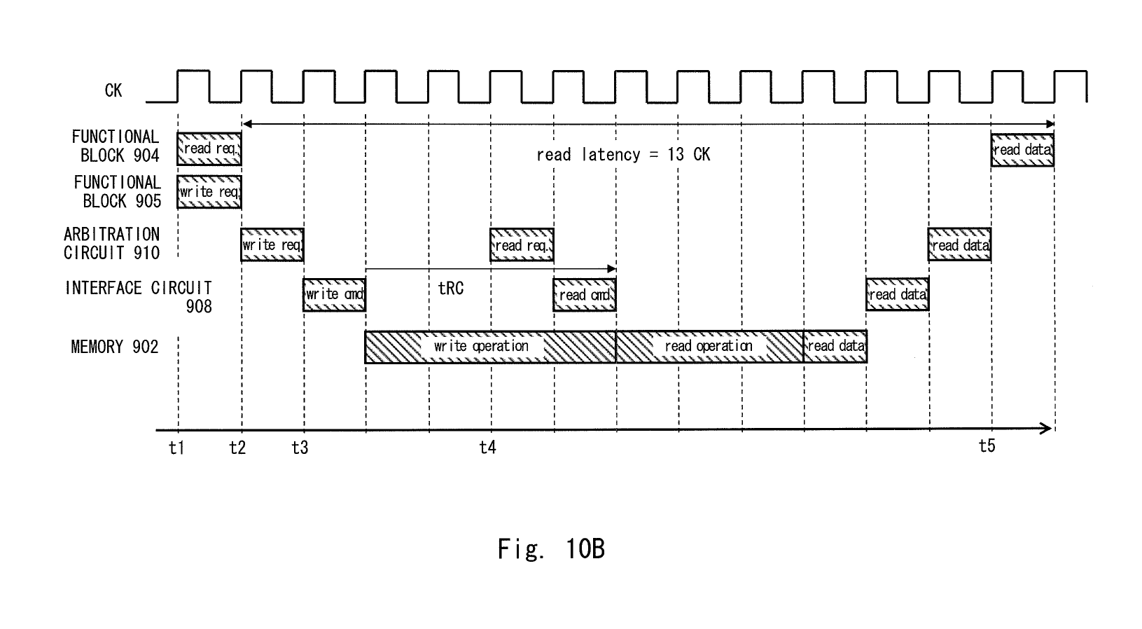

FIGS. 10A and 10B are timing charts showing operations of the semiconductor integrated circuit shown in FIG. 9. More specifically, FIG. 10A is a timing chart in a case where only the functional block 904 among the functional blocks 904 and 905 requests data reading from the memory 902. FIG. 10B is a timing chart in a case where the functional block 904 requests data reading from the memory 902 and the functional block 905 requests data writing to the memory 902 at the same time.

Firstly, the operation where only the functional block 904 among the functional blocks 904 and 905 requests data reading from the memory 902 is explained with reference to FIG. 10A. Firstly, the functional block 904 issues a read request to the arbitration circuit 910 (time t0). Since no request is issued from the other functional block, the arbitration circuit 910 accepts the read request received from the functional block 904 immediately and transfers the received read request to the interface circuit 908 (time t2). The interface circuit 908 generates a command signal and an address signal according to the read request received from the arbitration circuit 910 and outputs the generated signals to the memory 902 (time t3).

In the memory 902, the interface circuit 914 receives the command signal and the address signal output from the FPGA 901 and transfers the received signals to the memory core 912 located behind the interface circuit 914 (time t4). In the memory core 912, after the reading operation that takes a predetermined period, data stored in the memory cell specified by the address signal is read out (time t5). The interface circuit 914 outputs the data read from the memory core 912 to the FPGA 901 (time t5).

In the FPGA 901, the interface circuit 908 receives the data output from the memory 902 and transfers the received data to the arbitration circuit 910 (time t6). The arbitration circuit 910 transfers the data to the functional block 904, which has issued the read request (time t7). The functional block 904 takes in the data transferred from the arbitration circuit 910 in synchronization with a clock signal CK (time t8). In this manner, a series of operations for a data read request has been completed. In the example shown in FIG. 10A, the time period from when the functional block 904 issues the data read request to when the functional block 904 receives the data is nine clock cycles (time t1 to t8).

Next, the operation where the functional block 904 requests data reading from the memory 902 and the functional block 905 requests data writing to the memory 902 at the same time is explained with reference to FIG. 10B. Firstly, the functional block 904 issues a read request to the arbitration circuit 910 and the functional block 905 issues a write request to the arbitration circuit 910 at the same time (time t1).

The arbitration circuit 910 gives a higher priority, for example, to the write request issued from the functional block 905 and thereby transfers the write request to the interface circuit 908 (time t2). Note that the read request issued from the functional block 904 is put on hold while the writing operation is being performed according to the write request issued from the functional block 905. The interface circuit 908 generates a command signal, an address signal, and a write data signal according to the write request received from the arbitration circuit 910 and outputs the generated signals to the memory 902 (time t3).

Note that in the memory 902, the minimum value for the time interval (random cycle) tRC at which data read requests and data write requests are accepted is specified in advance according to the operation speed of the memory core 912. Therefore, the arbitration circuit 910 puts the read request issued from the functional block 904 on hold so that the interval of accesses from the FPGA 901 to the memory 902 becomes equal to or greater than this minimum value for the time interval tRC (time t2 to t4). At the time t4, the arbitration circuit 910 transfers the read request issued from the functional block 904, which has been put on hold, to the interface circuit 908. The subsequent operations are similar to those shown in FIG. 10A, and therefore their explanation is omitted here.

In the example shown in FIG. 10B, the time period from when the functional block 904 issues the data read request to when the functional block 904 receives the data is 13 clock cycles (time t1 to t5), which is longer than that of the example shown in FIG. 10A by four cycles. That is, when two or more functional blocks attempt to access the same memory at the same time, the data processing performance is lowered by an amount equivalent to the increase in the number of required clock cycles.

As described above, the shared-memory scheme is effective in that a memory can be shared by a plurality of functional blocks and therefore, for example, the redesign of the platform can be avoided even when the number of functional blocks within an FPGA is changed. However, there is a problem that when two or more functional blocks attempt to access the same memory at the same time, the data processing performance deteriorates.

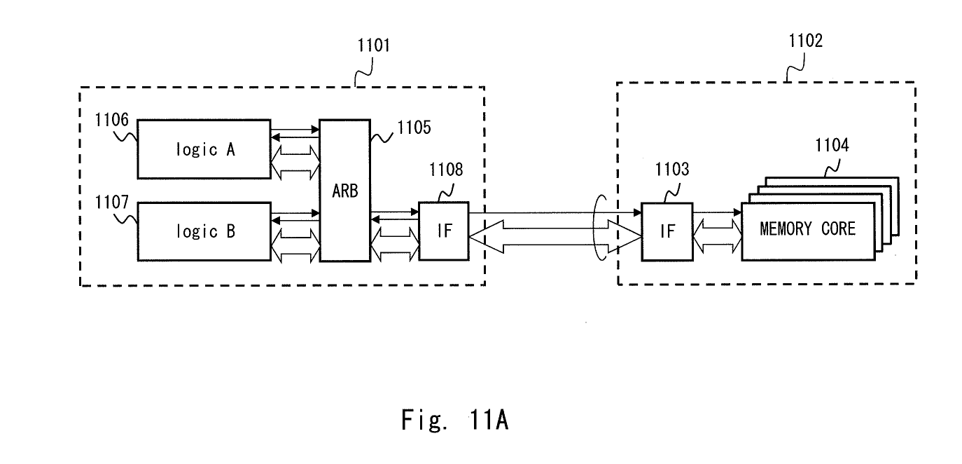

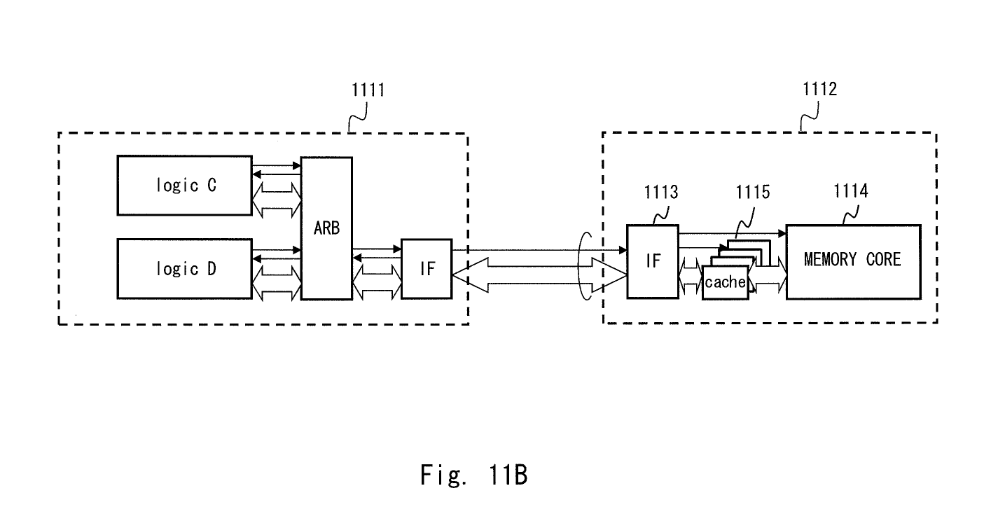

The inventors have made further examination to find a solution to this problem. FIGS. 11A and 11B are block diagrams showing semiconductor integrated circuits according to an idea prior to achieving the present invention.

In contrast to the semiconductor integrated circuit shown in FIG. 9, a semiconductor integrated circuit shown in FIG. 11A includes a memory 1102 adopting a multi-bank configuration. That is, the memory 1102 includes a plurality of independently-accessible memory cores 1104 connected to one interface circuit 1103. This semiconductor integrated circuit is explained hereinafter in a more detailed manner.

A semiconductor integrated circuit shown in FIG. 11A includes an FPGA 1101 including a plurality of functional blocks, and a memory (semiconductor apparatus) 1102. By programming the FPGA 1101, the FPGA 1101 includes two independent functional blocks 1106 and 1107, an interface circuit 1108, and an arbitration circuit 1105. The functional blocks 1106 and 1107 share the memory 1102 for the temporary saving of working data and the like. Note that the functional blocks 1106 and 1107, the interface circuit 1108, and the arbitration circuit 1105 correspond to the functional blocks 904 and 905, the interface circuit 908, and the arbitration circuit 910, respectively, shown in FIG. 9.

The memory 1102 includes a plurality of independently-accessible memory cores 1104 and an interface circuit 1103. The signal transmission between the functional blocks 1106 and 1107 and the plurality of memory cores 1104 is performed through the interface circuit 1108 on the FPGA 1101 side and the interface circuit 1103 on the memory 1102 side.

With the configuration like this, even when one of the plurality of memory cores 1104 is in operation, it is possible to accept the next read/write request without waiting for the completion of the currently-operated memory core operation if the next read/write request is for a memory core other than the currently-operated memory core. As a result, the memory 1102 shown in FIG. 11A can reduce the deterioration of the data processing performance in comparison to the memory 902 (or 903) shown in FIG. 9.

Further, in contrast to the semiconductor integrated circuit shown in FIG. 9, the semiconductor integrated circuit shown in FIG. 11B includes a memory 1112 including a cache circuit 1115. This semiconductor integrated circuit is explained hereinafter in a more detailed manner.

A semiconductor integrated circuit shown in FIG. 11B includes an FPGA 1111 including a plurality of functional blocks, and a memory (semiconductor apparatus) 1112. The circuit configuration of the FPGA 1111 is similar to the FPGA 1101 shown in FIG. 11A, and therefore its explanation is omitted. The memory 1112 includes one memory core 1114, an interface circuit 1113, and a cache circuit(s) 1115. The cache circuit 1115 is disposed between the interface circuit 1113 and the memory core 1114.

The cache circuit 1115 is a circuit that temporarily stores information stored in a frequently-accessed memory cell among a plurality of memory cells constituting the memory core 1114. For example, when data is to be read from a frequently-accessed memory cell, the data is read by accessing the cache circuit 1115, which has a high random cycle performance, instead of directly accessing the memory core 1114, which has a lower random cycle performance than that of the cache circuit 1115. As a result, the memory 1112 shown in FIG. 11B can reduce the deterioration of the data processing performance in comparison to the memory 902 (or 903) shown in FIG. 9.

Note that the signal transmission between the memory core 1114 and the cache circuit 1115 depends on the performance of the memory core 1114. However, since most of the data reading/writing operations are performed by using the cache circuit 1115, the effective random cycle performance of the memory 1112 improves.

Each of the memories 1102 and 1112 shown in FIGS. 11A and 11B improves the random cycle performance. However, their improvement effect is conditional. That is, the improvement is limited to the cases where read/write requests are issued for different memory cores or where read/write requests are issued for data stored in the cache circuit. When read/write requests are simultaneously issued from two or more functional blocks without satisfying this condition, the read/write requests are processed one by one in the descending order of their priorities under the control of the arbitration circuit. As a result, there has been a problem that the data processing performance deteriorates in the memories 1102 and 1112 shown in FIGS. 11A and 11B.

As described above, there has been a problem that the data processing performance deteriorates in the memories shown in FIG. 9 and FIGS. 11A and 11B. In particular, when the number of the functional blocks disposed in an FPGA increases, the arbitration operations occur frequently. Therefore, the deterioration of the data processing performance becomes more noticeable. On the other hand, when the number of the functional blocks that share one memory core is reduced in order to give priority to the performance, the number of memory cores becomes dependent on the number of the functional blocks, thus making the change of the platform unavoidable. Further, it raises another problem in terms of the cost that the increased memory capacity cannot be effectively used. To deal with the above-described problems, it has been desired to develop a memory (semiconductor apparatus) capable of preventing the deterioration of the data processing performance.

Embodiments according to the present invention are explained hereinafter with reference to the drawings. It should be noted that the drawings are made in a simple manner, and therefore the technical scope of the present invention should not be narrowly interpreted based on these drawings. Further, the same components are assigned with the same symbols and their duplicated explanation is omitted.

### First Embodiment

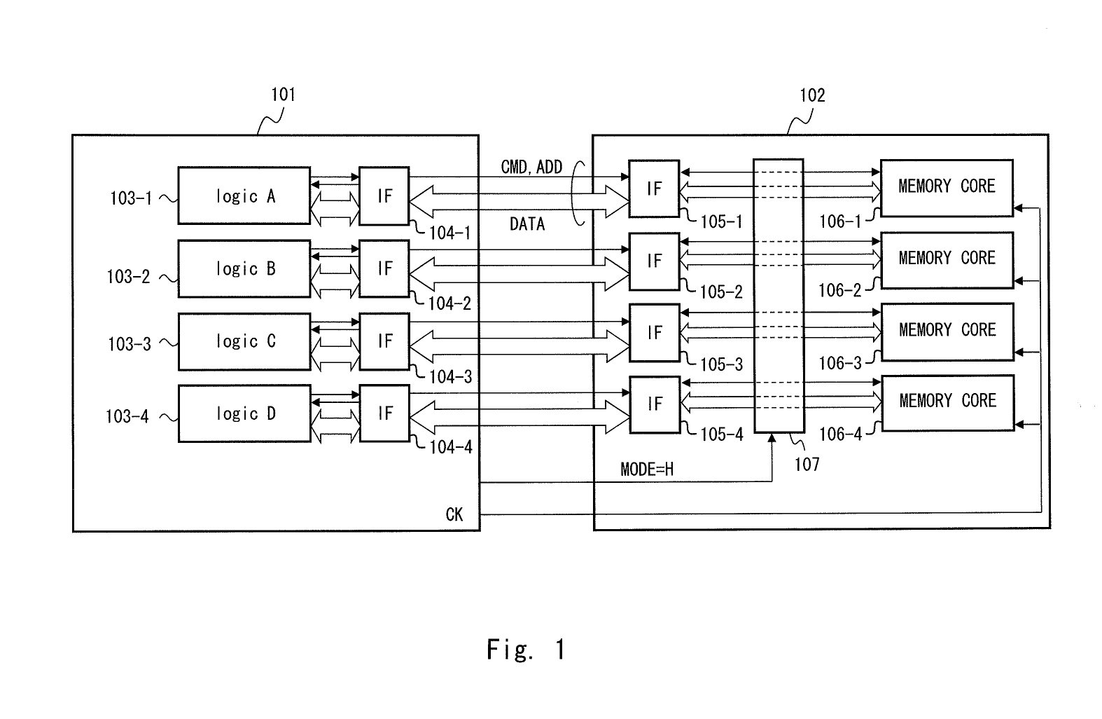

FIG. 1 is a block diagram showing a semiconductor integrated circuit including a memory (semiconductor apparatus) according to a first embodiment of the present invention. The memory according to this embodiment includes a plurality of independently-accessible memory cores, a plurality of bus-interface circuits that interface accesses from an external device to some of the plurality of memory cores, and a selection circuit that selects a signal path between the bus-interface circuits and the memory cores in such a manner that the bus-interface circuits are connected to mutually different memory cores. As a result, the memory according to this embodiment does not need to perform arbitration by using an arbitration circuit even when read/write requests are simultaneously issued from two or more functional blocks. Therefore, it is possible to prevent the deterioration of the data processing performance. The memory according to this embodiment is explained hereinafter in a more detailed manner.

A semiconductor integrated circuit shown in FIG. 1 includes an integrated circuit 101 including a plurality of functional blocks, and a memory 102. Note that the integrated circuit 101 is, for example, an FPGA (Field Programmable Gate Array) whose configuration can be changed by software. In the following explanation, an example in which the integrated circuit 101 is an FPGA (hereinafter called “PFGA 101”) is explained.

By programming the FPGA 101, the FPGA 101 includes four independent functional blocks 103-1 to 103-4 and interface circuits 104-1 to 104-4. The interface circuits 104-1 to 104-4 are circuits that interface accesses from the functional blocks 103-1 to 103-4, respectively, to the memory 102. Although not shown in the figure, that the FPGA 101 further includes a circuit that generates a clock signal CK and a circuit that generates a mode selection signal MODE (which is explained later).

The memory 102 includes four independently-accessible memory cores 106-1 to 106-4, interface circuits (bus-interface circuits) 105-1 to 105-4, and a selection circuit 107. Note that the memory cores 106-1 to 106-4 constitute a memory array. The signal transmission between the FPGA 101 and the memory 102 is performed through an external bus.

Each of the memory cores 106-1 to 106-4 includes a plurality of memory cells (storage area) for storing data. In each of the memory cores 106-1 to 106-4, data is written into a memory cell specified by an address signal, or data stored in a memory cell specified by an address signal is read out. Note that the switching between a data reading operation and a data writing operation is performed according to a write enable signal included in the command signal.

The interface circuits 105-1 to 105-4 are circuits that interface accesses from the FPGA 101 to some of the memory cores 106-1 to 106-4. The signal transmission between the interface circuits 105-1 to 105-4 and the memory cores 106-1 to 106-4 is performed through an internal bus whose connection state is selected by the selection circuit 107 (which is explained later).

The selection circuit 107 is disposed between the interface circuits 105-1 to 105-4 and the memory cores 106-1 to 106-4. The selection circuit 107 selects signal paths between the interface circuits 105-1 to 105-4 and the memory cores 106-1 to 106-4 based on a mode selection signal MODE supplied from the FPGA 101. More specifically, the selection circuit 107 selects the signal paths between the interface circuits 105-1 to 105-4 and the memory cores 106-1 to 106-4 in such a manner that interface circuits that are actually used are connected to mutually different memory cores. Note that “interface circuits that are actually used” mean circuits that actually interface accesses from the FPGA 101 to the memory array.

In the example shown in FIG. 1, the FPGA 101 outputs a mode selection signal MODE having a H-level to the memory 102. As a result, in the memory 102, the interface circuits 105-1 to 105-4 are connected to the memory cores 106-1 to 106-4 respectively through the selection circuit 107. That is, all of the interface circuits 105-1 to 105-4 are actually used (activated).

That is, in the example shown in FIG. 1, the signal transmission between the functional block 103-1 and the memory core 106-1 is performed through the interface circuit 104-1 on the FPGA 101 side and the interface circuit 105-1 on the memory 102 side. The signal transmission between the functional block 103-2 and the memory core 106-2 is performed through the interface circuit 104-2 on the FPGA 101 side and the interface circuit 105-2 on the memory 102 side. The signal transmission between the functional block 103-3 and the memory core 106-3 is performed through the interface circuit 104-3 on the FPGA 101 side and the interface circuit 105-3 on the memory 102 side. The signal transmission between the functional block 103-4 and the memory core 106-4 is performed through the interface circuit 104-4 on the FPGA 101 side and the interface circuit 105-4 on the memory 102 side.

In this manner, the interface circuits 105-1 to 105-4 that are actually used are connected to mutually different memory cores.

Note that as long as actually-used interface circuits are connected to mutually different memory cores, the signal paths may be selected in a different fashion from the above-described example. For example, the interface circuit 105-1 may be connected to the memory core 106-2 while the interface circuit 105-2 may be connected to the memory core 106-1.

Note also that the FPGA 101 generates a mode selection signal MODE having a signal level according to the number of functional blocks that need to access the memory 102, and outputs the generated mode selection signal MODE to the memory 102. Further, the FPGA 101 generates a clock signal CK and outputs the generated clock signal CK to the memory 102. The memory cores 106-1 to 106-4 operates in synchronization with this clock signal CK. Therefore, the memory cores 106-1 to 106-4 can operate in synchronization with this clock signal CK at all times irrespective of the signal paths selected by the selection circuit 107.

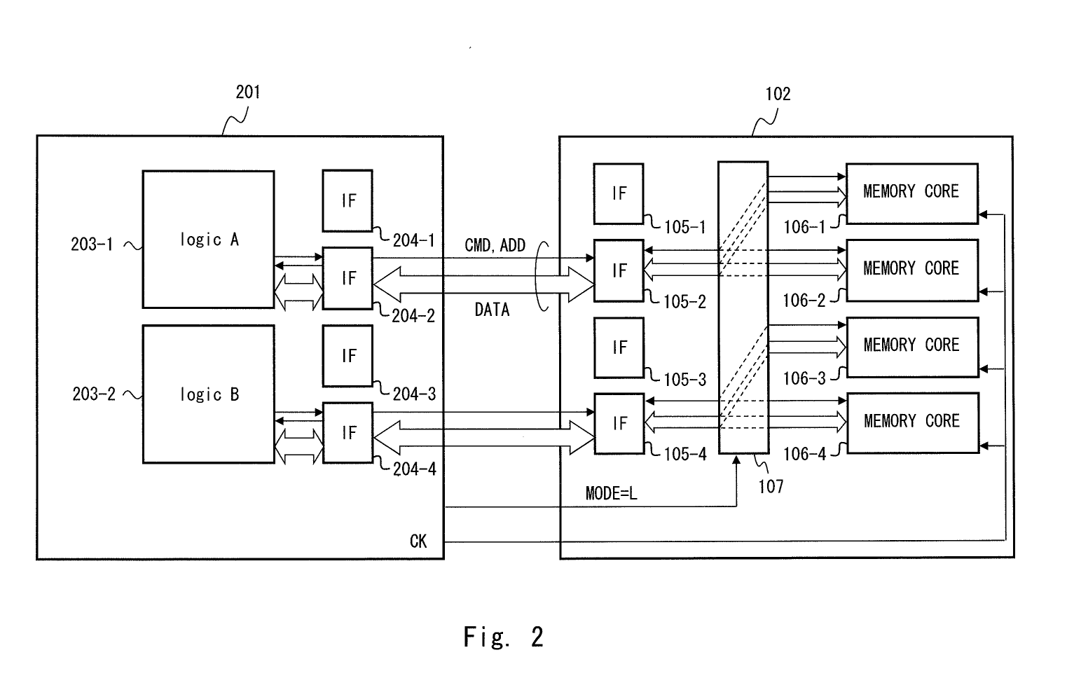

In a semiconductor integrated circuit shown in FIG. 2, the FPGA 101 shown in FIG. 1 is reprogrammed and denoted as “FPGA 201”. Specifically, the FPGA 201 is reprogrammed so that it has two independent functional blocks 203-1 and 203-2 and interface circuits 204-1 to 204-4. The remaining circuit configuration is similar to that shown in FIG. 1, and therefore its explanation is omitted here.

The interface circuits 204-2 and 204-4 are circuits that interface accesses from the functional blocks 203-1 and 203-2, respectively, to the memory 102. Meanwhile, the interface circuits 204-1 and 204-3 are not used for the interface with the memory 102.

In the example shown in FIG. 2, the FPGA 201 outputs a mode selection signal MODE having a L-level to the memory 102. As a result, in the memory 102, the interface circuit 105-2 is connected to the memory cores 106-1 and 106-2 through the selection circuit 107, and the interface circuit 105-4 is connected to the memory cores 106-3 and 106-4 through the selection circuit 107. That is, among the interface circuits 105-1 to 105-4, only the interface circuits 105-2 and 105-4 are actually used (activated).

That is, in the example shown in FIG. 2, the signal transmission between the functional block 203-1 and the memory cores 106-1 and 106-2 is performed through the interface circuit 204-2 on the FPGA 201 side and the interface circuit 105-2 on the memory 102 side. The signal transmission between the functional block 203-2 and the memory cores 106-3 and 106-4 is performed through the interface circuit 204-4 on the FPGA 201 side and the interface circuit 105-4 on the memory 102 side.

As described above, the interface circuits 105-2 and 105-4 that are actually used are connected to mutually different memory cores.

Meanwhile, the interface circuits 105-1 and 105-3 are not used. Therefore, instead of supplying a signal from the FPGA 201, a fixed signal (predetermined logic level voltage), for example, is supplied to the interface circuits 105-1 and 105-3. As a result, it is possible to prevent the input terminal(s) from becoming an opened state and thereby prevent the floating state.

Note that as long as actually-used interface circuits are connected to mutually different memory cores, the signal paths may be selected in a different fashion from the above-described example. For example, the interface circuit 105-2 may be connected only to the memory core 106-2 while the interface circuit 105-4 may be connected only to the memory core 106-4.

As described above, in the memory 102 according to this embodiment of the present invention, the selection circuit 107 selects signal paths between interface circuits that are actually used and memory cores in such a manner that the interface circuits are connected to mutually different memory cores. As a result, the memory 102 according to this embodiment does not need to perform arbitration by using an arbitration circuit even when read/write requests are simultaneously issued from two or more functional blocks. Therefore, it is possible to prevent the deterioration of the data processing performance. Note that although the number of the actually-used interface circuits is four or two in the above-described examples, the present invention is not limited to those configurations. The number of interface circuits that are actually used can be arbitrarily determined.

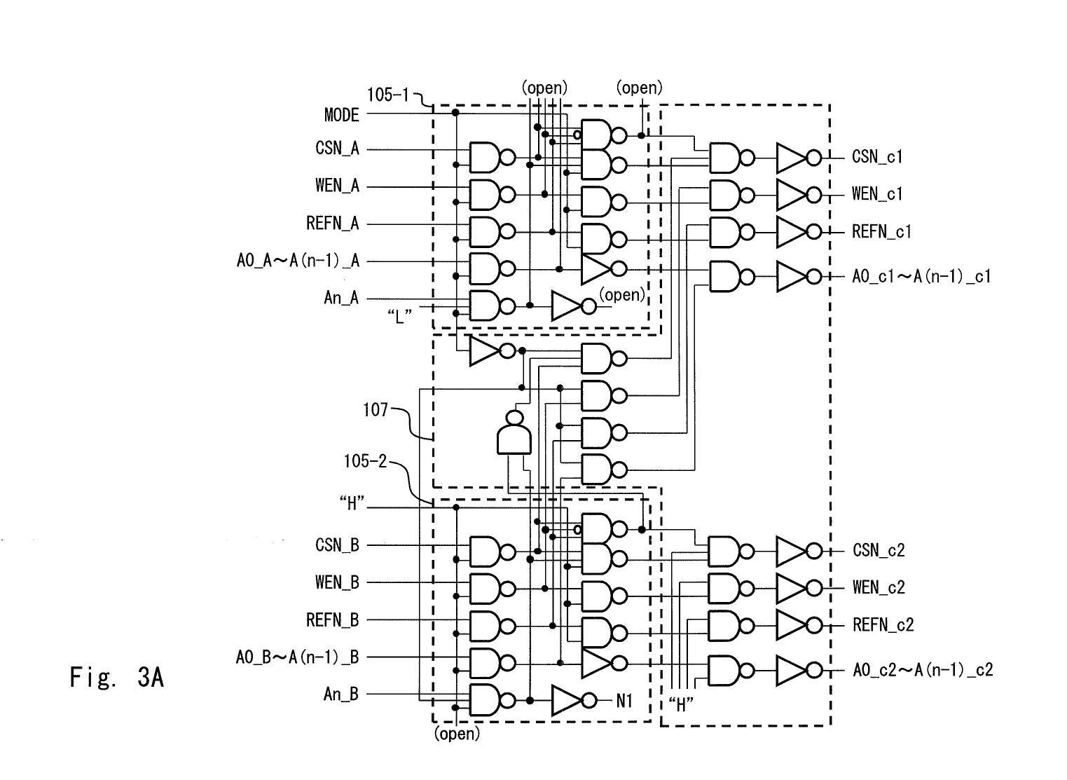

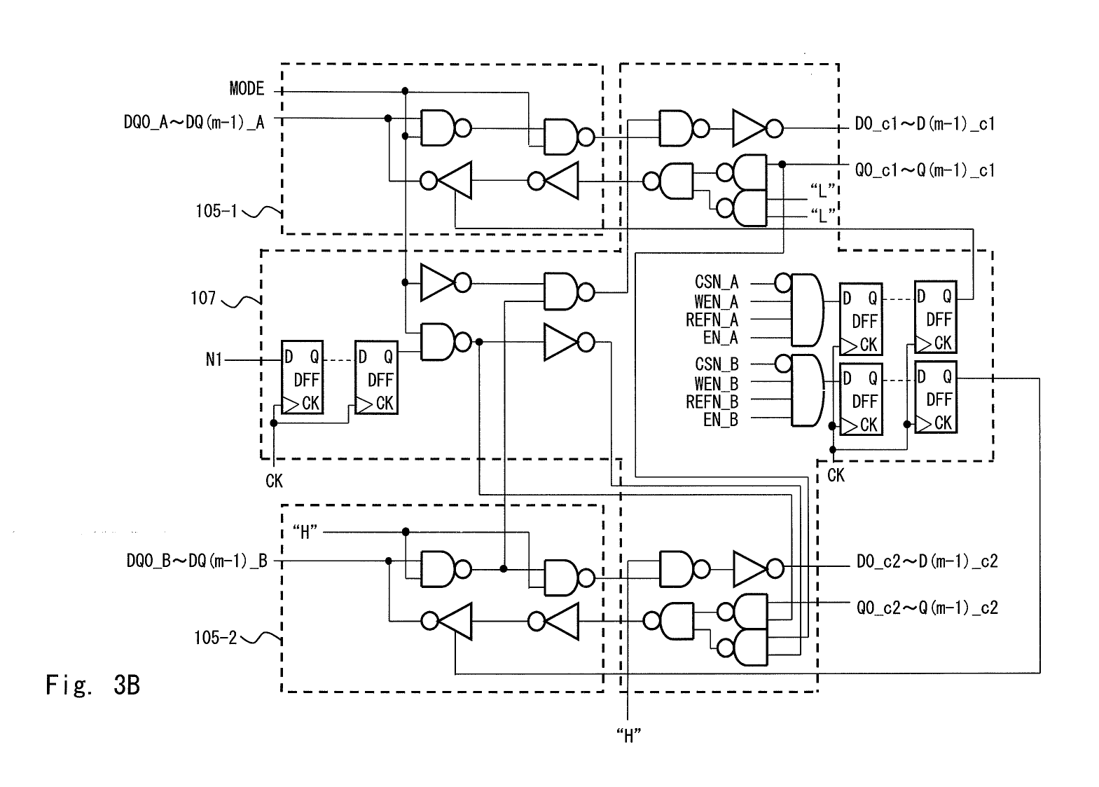

FIGS. 3A and 3B are examples showing parts of the interface circuits 105-1 and 105-2 and the selection circuit 107 disposed in the memory 102 shown in FIG. 1. FIG. 3A mainly shows a circuit configuration on the signal path of the address signal and the command signal, and FIG. 3B mainly shows a circuit configuration on the signal path of the data signal.

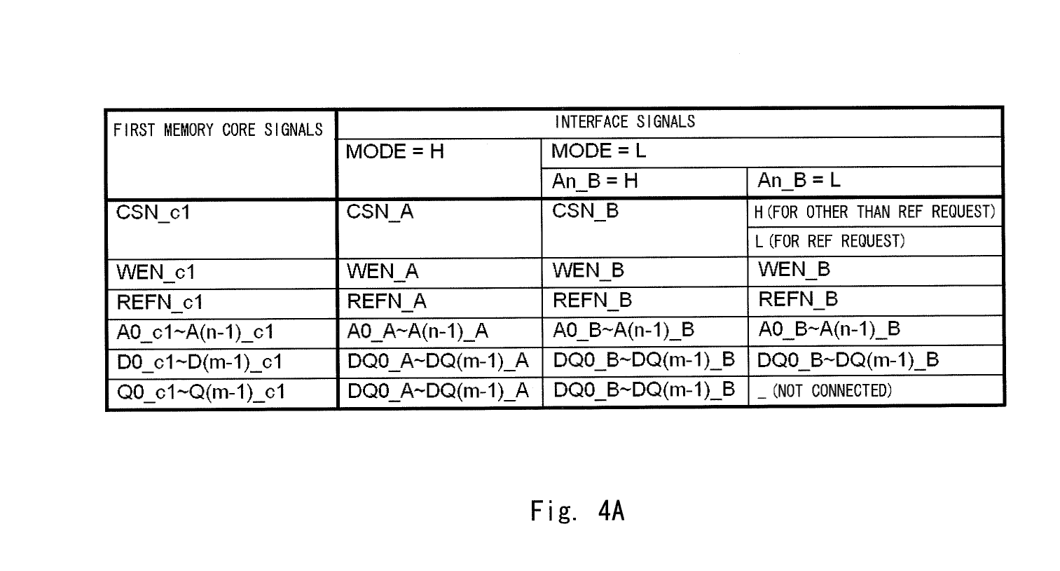

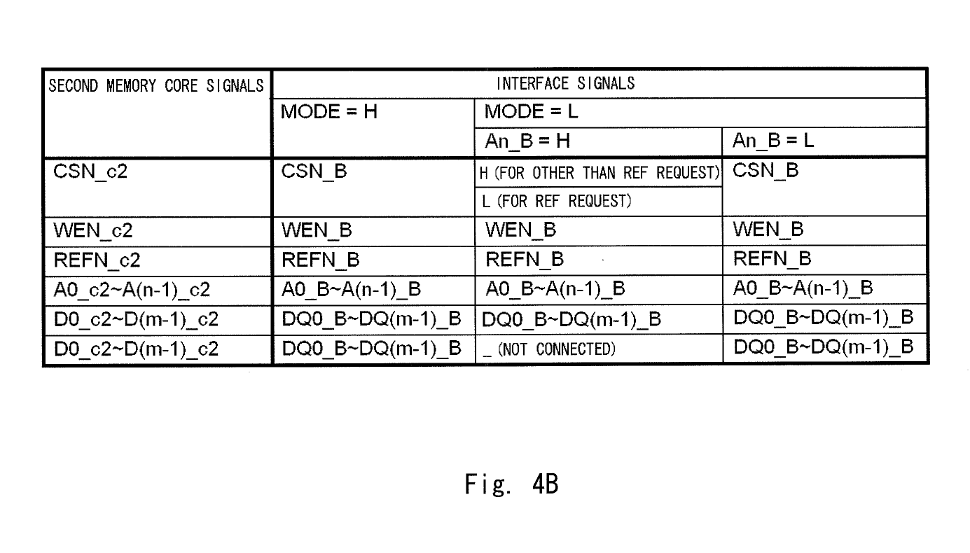

Further, FIGS. 4A and 4B are tables showing signal path relations between the interface circuits 105-1 and 105-2 and the memory cores 106-1 and 106-2. More specifically, FIG. 4A is a table showing interface signals that are selected as first memory core signals for each combination of the signal level of the mode selection signal MODE and the signal level of an extended address signal An_B. FIG. 4B is a table showing interface signals that are selected as second memory core signals for each combination of the signal level of the mode selection signal MODE and the signal level of the extended address signal An_B. Note that the signal path relations between the interface circuits 105-3 and 105-4 and the memory cores 106-3 and 106-4 are similar to those between the interface circuits 105-1 and 105-2 and the memory cores 106-1 and 106-2, and therefore their explanation is omitted here.

As shown in FIGS. 3A and 3B, the interface circuits 105-1 and 105-2 and the selection circuit 107 are formed from a plurality of logic gates. Note that in the example shown in FIGS. 3A and 3B, while the interface circuit 105-1 is sometimes not used (not activated), the interface circuit 105-2 is used (activated) at all times. Further, in the example shown in FIGS. 3A and 3B, the interface circuits have the same circuit configuration as each other in order to make their characteristics identical to each other as much as possible.

Firstly, as shown in FIG. 3A, the interface circuit 105-1 receives a chip selection signal CSN_A, a write enable signal WEN_A, and a refresh signal REFN_A from the FPGA as command signals. Further, the interface circuit 105-1 receives a mode selection signal MODE, n-bit address signal A0_A to A(n−1)_A (n is natural number) from the FPGA, and also receives an extended address signal An_A from the FPGA as a (n+1)th-bit address signal.

Meanwhile, the interface circuit 105-2 receives a chip selection signal CSN_B, a write enable signal WEN_B, and a refresh signal REFN_B as command signals from the FPGA. Further, the interface circuit 105-2 receives a mode selection signal MODE, n-bit address signal A0_B to A(n−1)_B (n is natural number) from the FPGA, and also receives an extended address signal An_B from the FPGA as a (n+1)th-bit address signal. Note that the signals that are transmitted/received between the interface circuits 105-1 and 105-2 and the FPGA are referred to as “interface signals” in FIGS. 4A and 4B.

The selection circuit 107 selects either the command signal and the n-bit address signal received by the interface circuit 105-1 or the command signal and the n-bit address signal received by the interface circuit 105-2 according to the mode selection signal MODE, and outputs the selected signals to the memory core 106-1 as a chip selection signal CSN_c1, a write enable signal WEN_c1, a refresh signal REFN_c1, and an address signal A0_c1 to A(n−1) c1 (which are referred to as “first memory core signals” in FIG. 4A).

Further, the selection circuit 107 also outputs the command signal and the n-bit address signal received by the interface circuit 105-2 to the memory core 106-1 as a chip selection signal CSN_c2, a write enable signal WEN_c2, a refresh signal REFN_c2, and an address signal A0_c2 to A(n−1) c2 (which are referred to as “second memory core signals” in FIG. 4B).

Note that in the example shown in FIGS. 3A and 3B, there are cases where, instead of the chip selection signal received by the interface circuit, a wait command is output as the chip selection signal CSN_c1 or CSN_c2. Such cases will be explained later in detail.

For example, when the mode selection signal MODE is at a H-level, the interface circuit 105-1 is connected to the memory core 106-1 through the selection circuit 107 and the interface circuit 105-2 is connected to the memory core 106-2 through the selection circuit 107. That is, both of the interface circuits 105-1 and 105-2 are actually used (activated). As a result, the interface circuit 105-1 transmits the command signal and the n-bit address signal received from the FPGA to the memory core 106-1 as the chip selection signal CSN_c1, the write enable signal WEN_c1, the refresh signal REFN_c1, and the address signal A0_c1 to A(n−1)_c1. Further, the interface circuit 105-2 transmits the command signal and the n-bit address signal received from the FPGA to the memory core 106-2 as the chip selection signal CSN_c2, the write enable signal WEN_c2, the refresh signal REFN_c2, and the address signal A0_c2 to A(n−1)_c2.

Note that in this state, the (n+1)th-bit address signals An_A and An_B of both interface circuits are not used and thereby not activated.

On the other hand, when the mode selection signal MODE is at a L-level, the interface circuit 105-1 is not connected to any of the memory cores while the interface circuit 105-2 is connected to the memory cores 106-1 and 106-2 through the selection circuit 107. That is, the interface circuit 105-1 is not used (not activated) while the interface circuit 105-2 is actually used (activated). As a result, the interface circuit 105-2 transmits the command signal and the n-bit address signal received from the FPGA to the memory core 106-1 as the chip selection signal CSN_c1, the write enable signal WEN_c1, the refresh signal REFN_c1, and the address signal A0_c1 to A(n−1)_c1, and also transmits those signals to the memory core 106-2 as the chip selection signal CSN_c2, the write enable signal WEN_c2, the refresh signal REFN_c2, and the address signal A0_c2 to A(n−1)_c2.

Note that in this state, whether the access is made to the memory core 106-1 or the memory core 106-2 is determined according to the signal level of the (n+1)th-bit address signal (extended address signal) An_B of the interface circuit 105-2. In the example shown in FIGS. 3A and 3B, when the extended address signal An_B is at a H-level, the chip selection signal CSN_B is transmitted to the memory core 106-1 while a wait command (H-level signal) is transmitted to the memory core 106-2. That is, it is determined that the access is made to the memory core 106-1. On the other hand, when the extended address signal An_B is at a L-level, the chip selection signal CSN_B is transmitted to the memory core 106-2 while a wait command (H-level signal) is transmitted to the memory core 106-1. That is, it is determined that the access is made to the memory core 106-2.

However, if a refresh request occurs, that is, if the refresh signal REFN_B is activated, both of the memory cores 106-1 and 106-2 are refreshed by the refresh signal REFN_B. In the example shown in FIGS. 3A and 3B, when a refresh request occurs, the wait command that has been supplied to either one of the memory cores is changed from the H-level to a L-level.

Next, as shown in FIG. 3B, the interface circuit 105-1 transmits/receives a m-bit data signal DQ0_A to DQ(m−1)_A (m is natural number) to/from the FPGA (101 or 201). The interface circuit 105-2 transmits/receives a m-bit data signal DQ0_B to DQ(m−1)_B to/from the FPGA (101 or 201).

In a data writing operation, the selection circuit 107 selects either a data signal that the interface circuit 105-1 has received from the FPGA or a data signal that the interface circuit 105-2 has received from the FPGA according to the mode selection signal MODE, and outputs the selected data signal to the memory core 106-1 as a write data signal D0_c1 to D(m−1)_c1. Further, the selection circuit 107 outputs a data signal that the interface circuit 105-2 has received from the FPGA to the memory core 106-2 as a write data signal D0_c2 to D(m−1)_c2.

In a data reading operation, the selection circuit 107 outputs a data signal Q0_c1 to Q(m−1)_c1 read from the memory core 106-1 to either the interface circuit 105-1 or the interface circuit 105-2 according to the mode selection signal MODE. Further, the selection circuit 107 outputs a data signal Q0_c2 to Q(m−1)_c2 read from the memory core 106-2 to the interface circuit 105-2.

For example, when the mode selection signal MODE is at a H-level, the interface circuit 105-1 is connected to the memory core 106-1 through the selection circuit 107 and the interface circuit 105-2 is connected to the memory core 106-2 through the selection circuit 107. That is, both of the interface circuits 105-1 and 105-2 are actually used (activated).

As a result, in a data writing operation, the interface circuit 105-1 transmits a data signal received from the FPGA to the memory core 106-1 as a write data signal D0_c1 to D(m−1)_c1. Further, the interface circuit 105-2 transmits a data signal received from the FPGA to the memory core 106-2 as a write data signal D0_c2 to D(m−1)_c2.

On the other hand, in a data reading operation, a data signal Q0_c1 to Q(m−1)_c1 read from the memory core 106-1 is transmitted to the interface circuit 105-1. Further, a data signal Q0_c2 to Q(m−1)_c2 read from the memory core 106-2 is transmitted to the interface circuit 105-2.

For example, when the mode selection signal MODE is at a L-level, the interface circuit 105-1 is not connected to any memory core and the interface circuit 105-2 is connected to the memory cores 106-1 and 106-2 through the selection circuit 107. That is, the interface circuit 105-1 is not used (not activated) while the interface circuit 105-2 is actually used (activated).

As a result, in a data writing operation, the interface circuit 105-2 transmits a data signal received from the FPGA to the memory core 106-1 as a write data signal D0_c1 to D(m−1)_c1, and also transmits the data signal to the memory core 106-2 as a write data signal D0_c2 to D(m−1)_c2. Note that whether the data is written into the memory core 106-1 or the memory core 106-2 is determined according to the signal level of the (n+1)th-bit address signal (extended address signal) An_B of the interface circuit 105-2 as described above. In the example shown in FIGS. 3A and 3B, when the extended address signal An_B is at a H-level, the data is written into the memory core 106-1. On the other hand, when the extended address signal An_B is at a L-level, the data is written into the memory core 106-2.

On the other hand, in a data reading operation, either a data signal Q0_c1 to Q(m−1)_c1 read from the memory core 106-1 or a data signal Q0_c2 to Q(m−1)_c2 read from the memory core 106-2 is transmitted to the interface circuit 105-2. Note that whether the data is read from the memory core 106-1 or the memory core 106-2 is determined according to the signal level of the (n+1)th-bit address signal An_B of the interface circuit 105-2 as described above. In the example shown in FIGS. 3A and 3B, when the extended address signal An_B is at a H-level, the data is read from the memory core 106-1. On the other hand, when the extended address signal An_B is at a L-level, the data is read from the memory core 106-2.

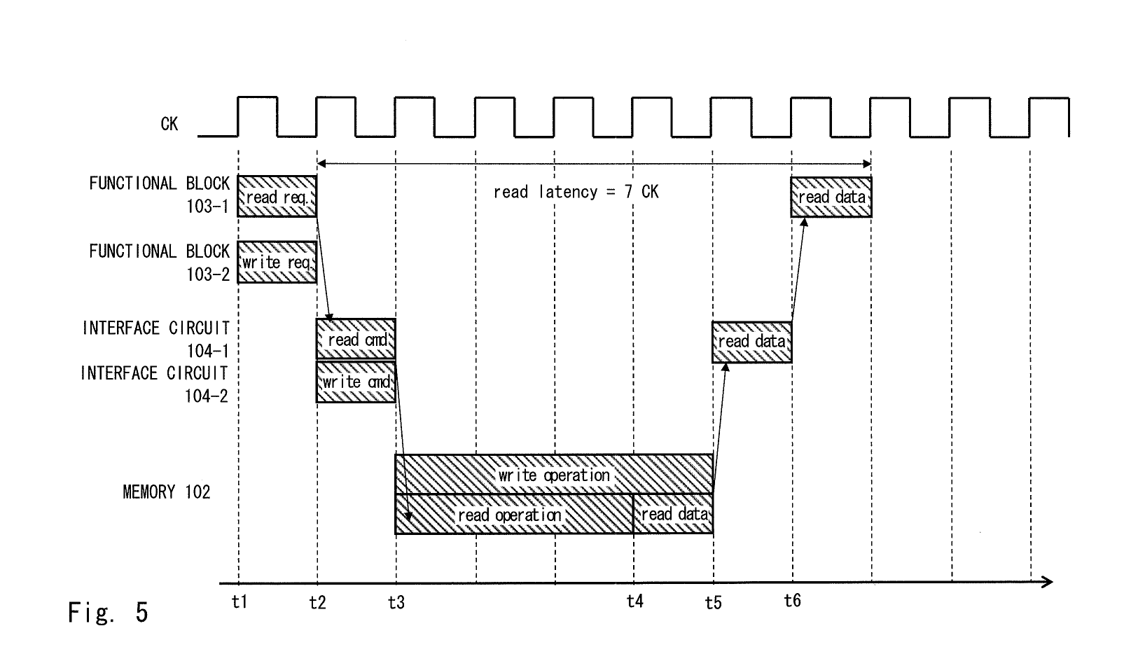

FIG. 5 is a timing chart showing an example of an operation of the semiconductor integrated circuit shown in FIG. 1. More specifically, FIG. 5 shows a timing chart of a case where the functional block 103-1 requests data reading from the memory 102 and the functional block 103-2 requests data writing to the memory 102 at the same time. That is, FIG. 5 shows a timing chart under the same condition as that of the timing chart shown in FIG. 10B.

Firstly, the functional block 103-1 issues a data read request to the interface circuit 104-1 and the functional block 103-2 issues a data write request to the interface circuit 104-2 at the same time (time t1). In this way, the read request and the write request issued from the functional blocks 103-1 and 103-2 are directly transmitted to the interface circuits 104-1 and 104-2 without being arbitrated by an arbitration circuit.

The interface circuit 104-1 generates a command signal and an address signal according to the read request received from the functional block 103-1 and outputs the generated signals to the memory 102. At the same time, the interface circuit 104-2 generates a command signal, an address signal, and a write data signal according to the write request received from the functional block 103-2 and outputs the generated signals to the memory 102 (time t2).

In the memory 102, the interface circuit 105-1 receives the command signal and the address signal output from the FPGA 101 and transfers the received signals to the memory core 106-1 located behind the interface circuit 105-1 (time t3). At the same time, the interface circuit 105-2 receives the command signal, the address signal, and the write date signal output from the FPGA 101 and transfers the received signals to the memory core 106-2 located behind the interface circuit 105-2 (time t3). In this manner, in the memory 102 according to this embodiment of the present invention, the interface circuits 105-1 and 105-2 that are actually used are connected to mutually different memory cores. Therefore, even when read/write requests are simultaneously issued from two or more functional blocks, these requests are processed in parallel without being arbitrated by an arbitration circuit.

In the memory core 106-1, after the reading operation that takes a predetermined period (time t3 to t4), data stored in the memory cell specified by the address signal is read out (time t4). The interface circuit 105-1 outputs the data read from the memory core 106-1 to the FPGA 101 (time t4). Meanwhile, the memory core 106-2 operates in parallel with the memory core 106-1, and after the writing operation that takes a predetermined period, the data is written into the memory cell specified by the address signal (time t3 to t5).

In the FPGA 101, the interface circuit 104-1 receives the data output from the memory 102 and transfers the received data to the functional block 103-1, which has issued the read request (time t5). The functional block 103-1 takes in the data transferred from the interface circuit 104-1 in synchronization with the clock signal CK (time t6). In this manner, a series of operations for a data read request and a data write request has been completed.

In the example shown in FIG. 5, the time period from when the functional block 103-1 issues the data read request and the data write request to when the functional block 103-1 receives the data is seven clock cycles (time t1 to t6), which is shorter than that of the example under the same condition shown in FIG. 10B by six clock cycles. That is, the data processing performance is improved by an amount equivalent to the decrease in the number of required clock cycles.

Further, the processing time of the arbitration circuit is eliminated. Therefore, even when compared to the case where only the read request is issued as shown in FIG. 10A, the overall time period is reduced by two clock cycles.

As described above, in the memory (semiconductor apparatus) according to this embodiment of the present invention, the selection circuit selects signal paths between interface circuits that are actually used and memory cores in such a manner that the interface circuits are connected to mutually different memory cores. As a result, the memory according to this embodiment does not need to perform arbitration by using an arbitration circuit even when read/write requests are simultaneously issued from two or more functional blocks. Therefore, it is possible to prevent the deterioration of the data processing performance.

Further, even when read/write requests are simultaneously issued from two or more functional blocks, these read/write requests are accessed to mutually different memory cores. Therefore, even if the number of functional blocks is changed as in the case shown in FIG. 2, these functional blocks can invariably maintain specific performance.

### Second Embodiment

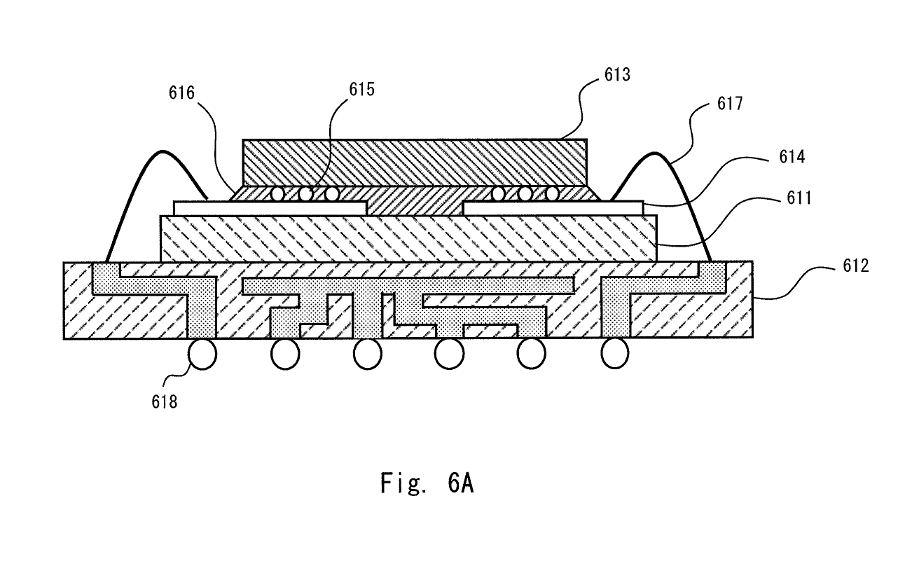

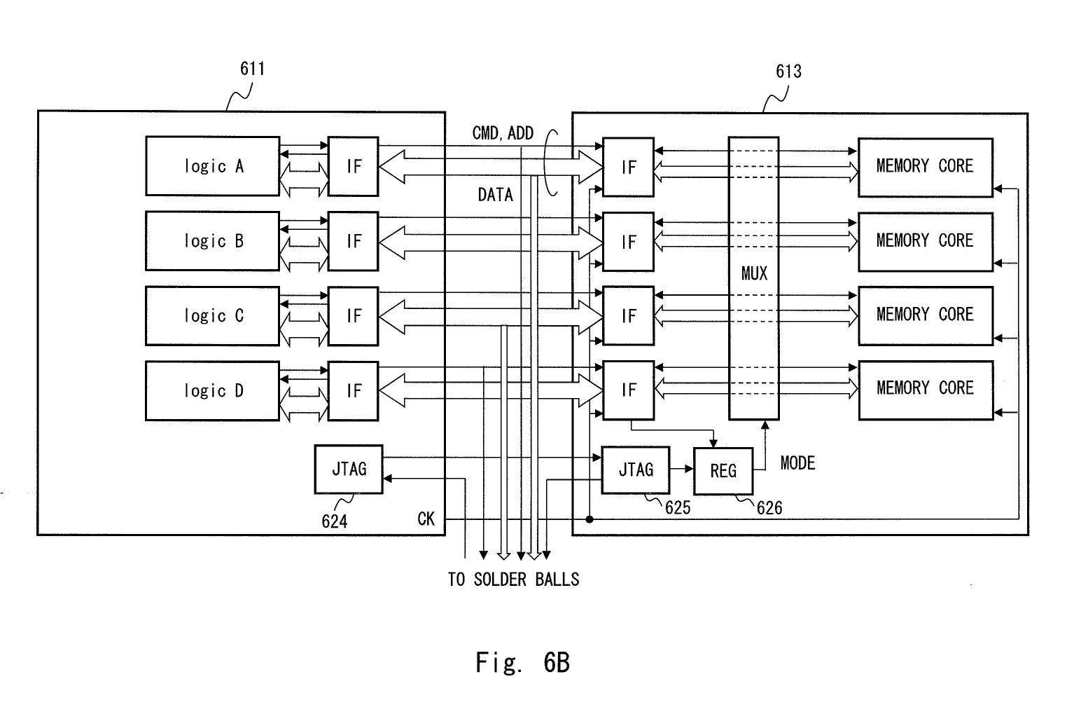

FIG. 6A is a cross section of a package that is obtained by integrating the FPGA 101 and the memory 102 constituting the semiconductor integrated circuit shown in FIG. 1 into one package. Further, FIG. 6B is a block diagram showing the semiconductor integrated circuit shown in FIG. 6A. Note that an FPGA 611 and a memory 613 shown in FIGS. 6A and 6B correspond to the FPGA 101 and the memory 102, respectively, shown in FIG. 1.

As shown in FIG. 6A, the chip of the FPGA 611 is mounted on an interposer substrate 612 in such a manner that the chip faces upward. The chip of the memory 613 is mounted on the FPGA 611 in such a manner that the chip faces downward. Further, a rewiring layer 614 is formed on the FPGA 611 between the FPGA 611 and the memory 613. In this rewiring layer 614, signal lines connecting between the FPGA 611 and the memory 613, various signal lines that are wired from the FPGA 611 chip or the memory 613 chip to the outside of the package, and power supply lines are formed. Note that bump electrodes 615 are disposed between the rewiring layer 614 and the memory 613 chip and electrically connect signal lines wired in the rewiring layer 614 to the memory 613.

Further, the space between the memory 613 chip and the rewiring layer 614 is filled with filling material 616 in order to prevent the misalignment of the bonding positions between the bump electrodes 615 and corresponding signal lines wired in the rewiring layer 614.

The external signal lines and the power supply lines, which are wired from the FPGA 611 or the memory 613 to the outside of the package, are connected to signal lines formed on the interposer substrate 612 through the rewiring layer 614 and bonding lines 617. These signal lines formed on the interposer substrate 612 are electrically connected to solder balls 618 disposed on the underside of the interposer substrate 612.

In FIG. 6B, the FPGA 611 and the memory 613 are electrically connected through various signal lines formed by the rewiring layer 614 and the bump electrodes 615. Further, the external signal lines and the power supply lines, which are wired from the FPGA 611 or the memory 613 to the outside of the package, are electrically connected to external devices or the like through the rewiring layer 614, the bonding lines 617, the interposer substrate 612, and the solder balls 618.

Further, to test the connection state of these various signal lines connecting between the FPGA 611 and the memory 613, the FPGA 611 and the memory 613 include JTAG circuits 624 and 625, respectively, which conform to IEEE1149.1. Note the JTAG circuits 624 and 625 are connected in a cascade configuration in accordance with the specifications.

The memory 613 further includes a register 626 that generates a mode selection signal MODE. The register 626 generates a mode selection signal MODE according to control signals supplied from the JTAG circuits 624 and 625. That is, the register 626 generates a mode selection signal MODE that can be arbitrarily set according to control signals supplied from the JTAG circuits 624 and 625. In this way, in the memory 613, signal paths between the interface circuits and the memory cores can be arbitrarily changed in the initial test that is carried out after the memory 613 is powered on. Note that it is also possible to set a desired mode selection signal MODE even in the operation state other the initial test, i.e., in the normal operation state. Therefore, in contrast to the memory 102, there is no need to provide a dedicated terminal for supplying an external mode selection signal MODE.

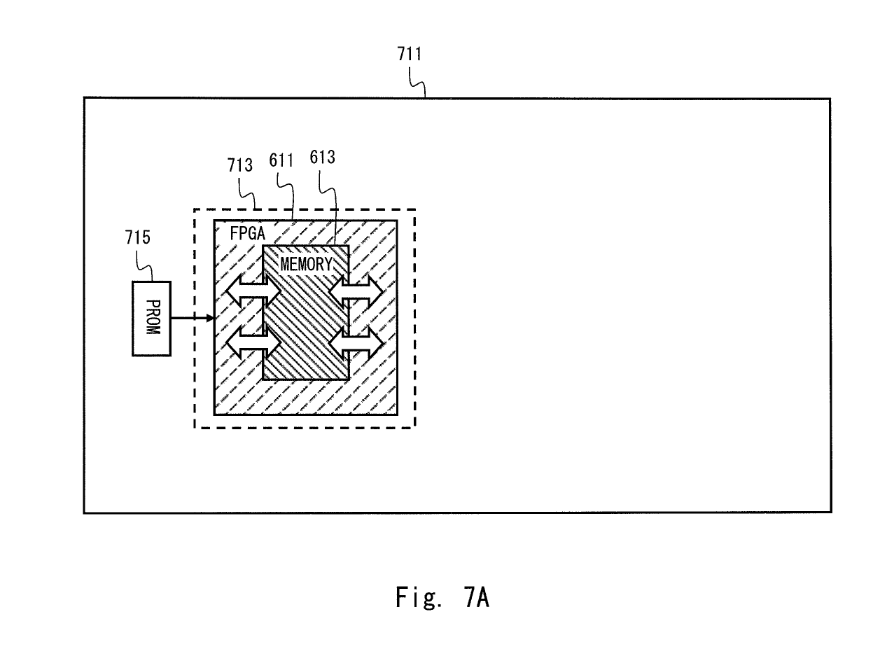

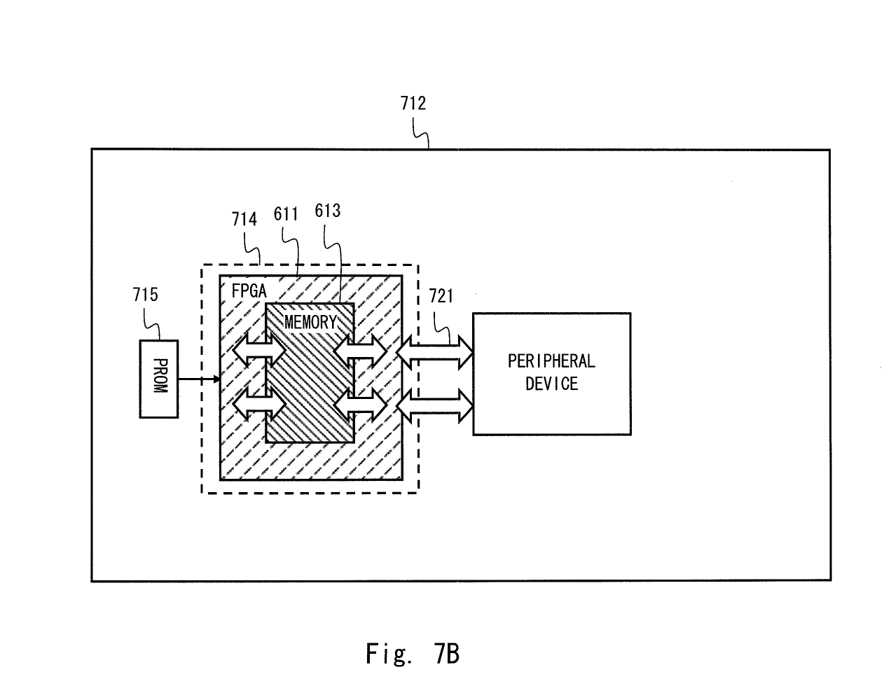

FIGS. 7A and 7B are conceptual diagrams of the semiconductor integrated circuit package shown in FIG. 6A when the semiconductor integrated circuit package is mounted on a system board. In FIG. 7A, a package 713 within which an FPGA 611 and a memory 613 are encapsulated and a nonvolatile memory 715 are mounted on a system board 711. Further, In FIG. 7B, a package 714 within which an FPGA 611 and a memory 613 are encapsulated and a nonvolatile memory 715 are mounted on a system board 712. Note that in the nonvolatile memory 715, a program that is used to determine the circuit configuration of the FPGA 611 and information that is used to set a mode selection signal MODE supplied to the selection circuit located within the memory 613 are stored. During the system start-up, the program and the setting information of the mode selection signal MODE stored in the nonvolatile memory 715 are transmitted to the FPGA 611 and the memory 613 respectively through the JTAG circuits 624 and 625.

Note that FIG. 7A shows an example in which the program and the setting information of the mode selection signal MODE stored in the nonvolatile memory 715 are adjusted so that the FPGA 611 has a similar circuit configuration to that of the FPGA 101 shown in FIG. 1. That is, the FPGA 611 includes a comparatively large number of functional blocks that need to access the memory 613. Therefore, all of a plurality of interface circuits provided in the memory 613 are actually used (activated).

Meanwhile, FIG. 7B shows an example in which the program and the setting information of the mode selection signal MODE stored in the nonvolatile memory 715 are adjusted so that the FPGA 611 has a similar circuit configuration to that of the FPGA 201 shown in FIG. 2. That is, the FPGA 611 includes a comparatively small number of functional blocks that need to access the memory 613. Therefore, some of a plurality of interface circuits provided in the memory 613 are not used (not activated). Note that the interface circuits on the FPGA 611 side that correspond to the non-activated interface circuits on the memory 613 side are connected, for example, to signal lines 721 of other peripheral devices through the solder balls 618 of the package that are electrically connected to the interface circuits and thereby used for other purposes.

As described above, even in such situations that the FPGA chip and the memory chip are encapsulated in one package and therefore the replacement of the chip is difficult, the FPGA can perform signal transmission with other peripheral devices. Therefore, the versatility of the FPGA is maintained.

### Third Embodiment

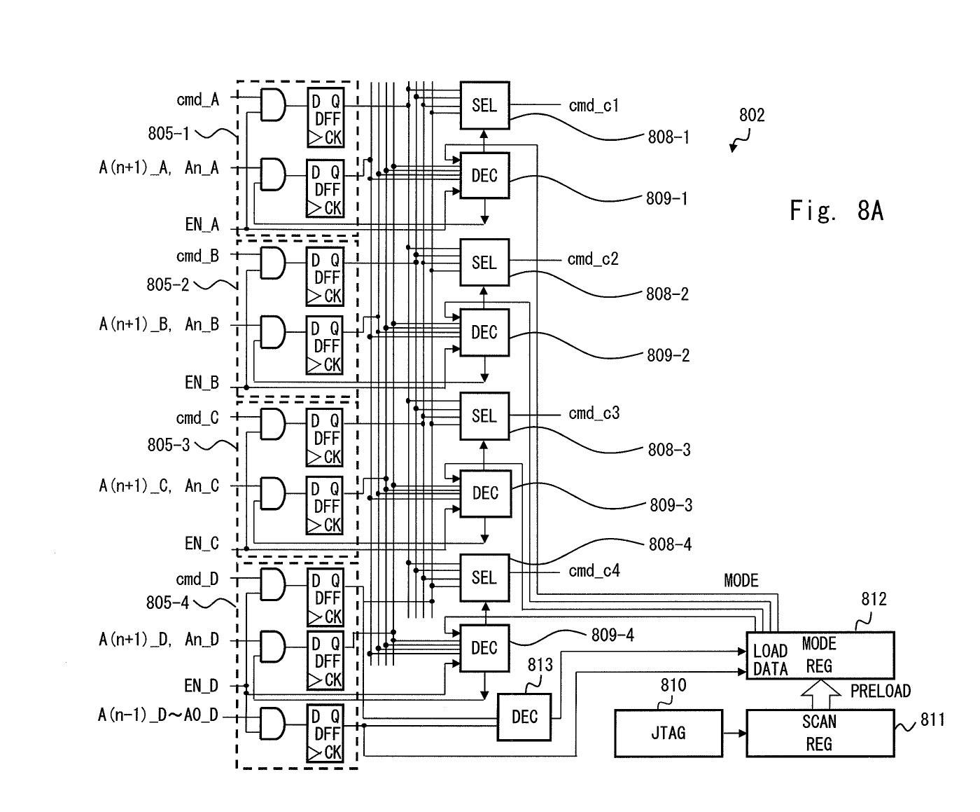

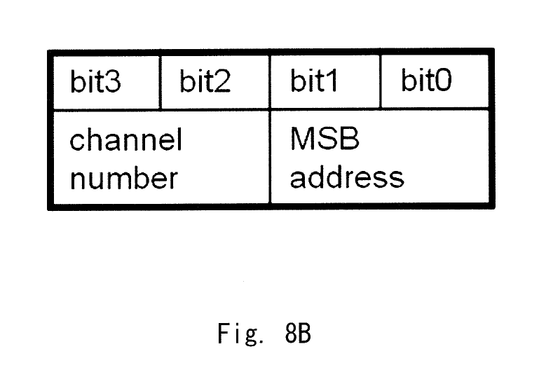

FIG. 8A is a circuit diagram showing a part of a memory (semiconductor apparatus) 802 according to a third embodiment of the present invention. When the replacement of the chip is difficult as described in the second embodiment, it is expected that the use of a memory whose connections can be configured in a more flexible manner than that of the memory 102 shown in FIGS. 3A and 3B can improve the usability. Therefore, the memory 802 according to this embodiment of the present invention adopts a circuit configuration in which the connections can be configured in a more flexible manner than that of the memory 102 shown in FIGS. 3A and 3B. Note that FIG. 8A mainly shows parts of interface circuits 805-1 to 805-4 and a selection circuit 807 provided in the memory 802.

As shown in FIG. 8A, the interface circuits 805-1 to 805-4 include input first stage circuits 803-1 to 803-4 respectively, each of which is composed of a plurality of AND circuits, and signal hold circuits 804-1 to 804-4 respectively, each of which is composed of a plurality of latches. The input first stage circuits 803-1 to 803-4 are circuits that switch whether the interface circuits 805-1 to 805-4, respectively, are activated or not.

For example, when externally-received enable signals EN_A to EN_D are at a L-level, the interface circuits 805-1 to 805-4 are inactivated. On the other hand, when the externally-received enable signals EN_A to EN_D are at a H-level, the interface circuits 805-1 to 805-4 are activated. Further, The signal hold circuits 804-1 to 804-4 are circuits that hold externally-received command signals cmd_A to cmd_D respectively and 2-bit extended address signals A(n+1)_A, An_A to A(n+1)_D, An_D respectively.

The selection circuit 807 includes selectors 808-1 to 808-4 and decode circuits 809-1 to 809-4. The selector 808-1 selects one of the signals held in the signal hold circuits 804-1 to 804-4 and outputs the selected signal as a command signal cmd_c1. The selector 808-2 selects one of the signals held in the signal hold circuits 804-1 to 804-4 and outputs the selected signal as a command signal cmd_c2. The selector 808-3 selects one of the signals held in the signal hold circuits 804-1 to 804-4 and outputs the selected signal as a command signal cmd_c3. The selector 808-4 selects one of the signals held in the signal hold circuits 804-1 to 804-4 and outputs the selected signal as a command signal cmd_c4. The decode circuits 809-1 to 809-4 generate switch signals that are used to switch the output of the selectors 808-1 to 808-4 respectively, and generate control signals that are used to switch whether the respective externally-received extended address signals are activated or not.

The memory 802 further includes a JTAG circuit 810 that acquires externally-supplied initial setting information during the system start-up, a register 811 that holds the initial setting information, a register 812 that generates a mode selection signal MODE based on the initial setting information held in the register 811, and a decode circuit 813 that determines a request command based on a command signal supplied to a predetermined one of the plurality of interface circuits and thereby updates the initial setting information. In the example shown in FIG. 8A, the interface circuit 805-4 is used as the predetermined one of the interface circuits. In this manner, in the initial test that is carried out after the memory 802 is powered on, the mode selection signal MODE is arbitrarily changed. Note that in the operation state other the initial test, i.e., in the normal operation state, the command signal cmd_D is determined by the decode circuit 813. Then, if it is a command instructing the update of the register 812, the setting information is updated. In this manner, a desired mode selection signal MODE can be set even in the operation state other the initial test, i.e., in the normal operation state. Therefore, in contrast to the memory 102, there is no need to provide a dedicated terminal for supplying an external mode selection signal MODE.

The register 812 generates four 4-bit mode selection signals MODE and outputs the generated signals to corresponding decode circuits 809-1 to 809-4. Note that in each mode selection signal MODE, the values of the upper two bits (channel number) are used to specify one of the interface circuits 805-1 to 805-4 and the values of the lower two bits (MSB address) are used to specify the value of the extended address signal (see FIG. 8B).

The decode circuit 809-1 specifies an interface circuit based on the valued of the higher two bits of the supplied mode selection signal MODE. Then, when the extended address signal received by that interface circuit matches the value of the lower two bits of the supplied mode selection signal MODE, the decode circuit 809-1 outputs the command signal received by that interface circuit (one of the command signals cmd_A to cmd_D) to the memory core 814-1 (not shown in FIG. 8A) as the command signal cmd_c1.

Similarly, the decode circuit 809-2 specifies an interface circuit based on the valued of the higher two bits of the supplied mode selection signal MODE. Then, when the extended address signal received by that interface circuit matches the value of the lower two bits of the supplied mode selection signal MODE, the decode circuit 809-2 outputs the command signal received by that interface circuit (one of the command signals cmd_A to cmd_D) to the memory core 814-2 (not shown in FIG. 8A) as the command signal cmd_c2.

Similarly, the decode circuit 809-3 specifies an interface circuit based on the valued of the higher two bits of the supplied mode selection signal MODE. Then, when the extended address signal received by that interface circuit matches the value of the lower two bits of the supplied mode selection signal MODE, the decode circuit 809-3 outputs the command signal received by that interface circuit (one of the command signals cmd_A to cmd_D) to the memory core 814-3 (not shown in FIG. 8A) as the command signal cmd_c3.

Similarly, the decode circuit 809-4 specifies an interface circuit based on the valued of the higher two bits of the supplied mode selection signal MODE. Then, when the extended address signal received by that interface circuit matches the value of the lower two bits of the supplied mode selection signal MODE, the decode circuit 809-4 outputs the command signal received by that interface circuit (one of the command signals cmd_A to cmd_D) to the memory core 814-4 (not shown in FIG. 8A) as the command signal cmd_c4.

In this manner, each of the memory cores 814-1 to 814-4 is connected to only one of the plurality of interface circuits. In other words, each interface circuit is connected to a mutually different memory core.

The circuit scale of the memory 802 shown in FIG. 8A is larger than that of the memory 102 shown in FIGS. 3A and 3B because the memory 802 includes the selection circuit 807 including a plurality of selectors and a plurality of decode circuits. Therefore, there was a possibility that the memory 802 shown in FIG. 8A has lower data processing performance in comparison to the memory 102 shown in FIGS. 3A and 3B. To cope with this problem, the memory 802 shown in FIG. 8A includes signal hold circuits (latches) in the interface circuits so that a pipeline operation can be performed.

Note that in the semiconductor integrated circuit including the memory 802 and the FPGA shown in FIG. 8A, when a data read request is issued from one functional block, the time period from when the functional block issues the data read request to when that functional block receives the data is nine clock cycles. This is equal to the number of clock cycles in the example under the same condition shown in FIG. 10A. Meanwhile, when a data read request and a data write request are simultaneously issued from two or more functional blocks, the time period from when one of the functional blocks issues the data read request to when that functional block receives the data is also nine clock cycles. This is shorter than that of the example under the same condition shown in FIG. 10B by four cycles. That is, in the memory according to this embodiment of the present invention, the data processing performance improves when a data read request and a data write request are simultaneously issued from two or more functional blocks.

As explained so far, in the memories (semiconductor apparatuses) according to the above-described embodiments of the present invention, the selection circuit selects signal paths between interface circuits that are actually used and memory cores in such a manner that the interface circuits are connected to mutually different memory cores. As a result, the memory according to this embodiment does not need to perform arbitration by using an arbitration circuit even when read/write requests are simultaneously issued from two or more functional blocks. Therefore, it is possible to prevent the deterioration of the data processing performance.

Note that the present invention is not limited to the above-described first to third embodiments and various modifications can be made without departing from the spirit and scope of the present invention. Although examples in which the memory includes four interface circuits and four memory cores are explained in the above-described first to third embodiments, the present invention is not limited these configurations. That is, the above-described circuit configuration can be changed to various circuit configurations including any given number of interface circuits and memory cores, provided that the requirement that the interface circuits that are actually used are connected to mutually different memory cores is satisfied.

Further, the circuit configurations shown in FIGS. 3A and 3B and FIG. 8A are shown as mere examples, and needless to say, they can be changed to other configurations in which similar processing can be performed.

While the invention has been described in terms of several embodiments, those skilled in the art will recognize that the invention can be practiced with various modifications within the spirit and scope of the appended claims and the invention is not limited to the examples described above.

Further, the scope of the claims is not limited by the embodiments described above.

Furthermore, it is noted that, Applicant's intent is to encompass equivalents of all claim elements, even if amended later during prosecution.

What is claimed is:

1. A semiconductor apparatus comprising:
a programmable logic chip configured to output a control signal; and
a memory chip coupled to the programmable logic chip, the memory chip including:
a plurality of memory cores;
a plurality of bus-interface circuits each configured to couple with the memory cores; and
a selection circuit configured to couple the memory cores with one of the bus-interface circuits in response to a predetermined logic level of the control signal.

2. The semiconductor apparatus according to claim 1,
wherein the selection circuit is further configured to couple the memory cores with the bus-interface circuits with one-to-one correspondence in response to another logic level of the control signal.

3. The semiconductor apparatus according to claim 2,
wherein each of the memory cores is accessed without an intervention of an arbitration circuit.

4. The semiconductor apparatus according to claim 2,
wherein each of the bus-interface circuits includes an input port configured to be terminated when the each of the bus-interface circuits is not coupled with any memory cores.

5. The semiconductor apparatus according to claim 2,
the programmable logic chip includes a plurality of interface circuit each coupled with the bus-interface circuits with one-to-one correspondence.

6. The semiconductor apparatus according to claim 2,
wherein the programmable logic chip is further configured to output a clock signal, and
wherein each of the memory cores is configured to operate with the clock signal.

7. A semiconductor apparatus comprising:
a plurality of memory cores;
a plurality of bus-interface circuits that interfaces an access from an external device to the plurality of memory cores; and
a selection circuit that selects a signal path between the bus-interface circuits and the memory cores in such a manner that the bus-interface circuits are connected to mutually different memory cores.

8. The semiconductor apparatus according to claim 7, an input terminal of a bus-interface circuit that is not connected to any of the memory cores, among the plurality of bus-interface circuits, is fixed at a predetermined logic level.

9. The semiconductor apparatus according to claim 7, wherein a storage area of a memory core for which a reading or writing operation is to be performed is specified by an address signal having a bit width according to a number of memory cores connected to the bus-interface circuit.

10. The semiconductor apparatus according to claim 7, wherein a refresh is performed for a memory core connected to a bus-interface circuit by an externally-supplied refresh signal supplied through that bus-interface circuit.

11. The semiconductor apparatus according to claim 7, wherein the plurality of memory cores operate in synchronization with a same clock signal.

12. The semiconductor apparatus according to claim 7, wherein the selection circuit selects the signal path based on an externally-supplied mode selection signal.

13. The semiconductor apparatus according to claim 7, further comprising a JTAG circuit that generates the mode selection signal,
wherein the selection circuit selects the signal path based on the mode selection signal generated by the JTAG circuit.

14. The semiconductor apparatus according to claim 13, wherein the mode selection signal is updated based on a command signal supplied through a predetermine bus-interface circuit among the plurality of bus-interface circuits.

15. A semiconductor apparatus comprising:
a plurality of bus-interface circuits that connect an external bus signal with an internal bus signal;
a plurality of memory cores, each of which separately comprises a bus-interface connectable to the internal bus signal; and
a selection circuit that selects a connection state of the internal bus signal between the plurality of bus-interface circuits and the plurality of memory cores, wherein
the selection circuit connects each of the memory cores with one of the bus-interface circuits based on externally-supplied setting information, and
when the bus-interface circuit is not connected to the memory core by the selection circuit, the but-interface circuit fixes at least one of the external bus signal to a predetermined logic level.

16. The semiconductor apparatus according to claim 15, wherein the selection circuit selectively connects each of the plurality of memory cores to one of the plurality of bus-interface circuits.
